(19) United States
(12) Patent Application Publication
(10) Pub. No.: US 2024/0351164 A1
(43) Pub. Date: Oct. 24, 2024

(54) PAD CONDITIONER

(71) Applicant: SAESOL Diamond Ind. Co., Ltd., Ansan-si (KR)

(72) Inventors: Ji Woo KIM, Siheung-si (KR); Sung Goo LEE, Siheung-si (KR)

(73) Assignee: SAESOL Diamond Ind. Co., Ltd., Ansan-si (KR)

(21) Appl. No.: 18/644,200

(22) Filed: Apr. 24, 2024

(30) Foreign Application Priority Data
Apr. 24, 2023 (KR) 10-2023-0053485

(51) Int. Cl. B24B 53/017

(52) U.S. Cl. CPC B24B 53/017

(57) ABSTRACT

A pad conditioner configured to dress a surface of a chemical mechanical polishing (CMP) pad according to an embodiment of the present invention may include a substrate, and a protruding member including a cutting part configured to cut the pad, a roughness control part configured to support the cutting part and restrict an indentation depth of the cutting part, and a body part protruding from the substrate and configured to support the roughness control part and provided in plural on the substrate, wherein the cutting parts may have different protrusion heights, and a protruding member including a cutting part with a relatively larger protrusion height and a protruding member including a cutting part with a relatively smaller protrusion height may be disposed mixedly at a set ratio.

### CROSS REFERENCE TO RELATED APPLICATION

The present application claims priority and the benefit of Korean Patent Application No. 10-2023-0053485, filed on Apr. 24, 2023 in the Korean Intellectual Property Office, the entire contents of which is incorporated herein for all purposes by this reference.

### BACKGROUND

### Field of the Invention

The present invention relates to a pad conditioner, and more specifically, to a pad conditioner for a chemical mechanical polishing (CMP) device used in a planarization operation of wafers.

### Description of the Related Art

A chemical mechanical polishing (CMP) device is a polishing device for obtaining the flatness of semiconductor wafers and polishes wafers by rotationally rubbing the wafers against a pad while supplying a slurry containing a polishing compound on the pad, and polishing performance is determined according to a surface state of the pad and various factors.

As a CMP polishing process progresses, the polishing ability of the wafer is reduced due to the slurry adsorbed on the pad, and thus a conditioner is needed to restore the performance of the pad, and a conditioning operation of restoring planarization and performance by cutting a pad surface on which the slurry is adsorbed using the conditioner is performed.

However, since conventional conditioners could not control the roughness formed on the pad surface in the conditioning process, there has been a problem in that the slurry is hardened by plastic deformation and scratches are formed on a wafer surface due to protruded portions.

In addition, due to the miniaturization and high stacking of semiconductor processes, the CMP polishing process requires a higher level of wafer polishing uniformity and performance deviation between products than those in the past, and the development for a conditioner technology capable of meeting such a demand is required.

### DOCUMENTS OF RELATED ART

(Patent Document 1) Korean Patent Application Laid-Open No. 10-2009-0078647

### SUMMARY OF THE INVENTION

The present invention has been made in efforts to solve the problem and is directed to providing a pad conditioner capable of minimizing roughness generated during a conditioning operation and reducing performance deviation between products.

The object of the present invention is not limited to the above-described object, and other objects that are not mentioned will be able to be clearly understood by those skilled in the art from the following description.

A pad conditioner configured to dress a surface of a chemical mechanical polishing (CMP) pad according to an embodiment of the present invention may include a substrate, and a protruding member including a cutting part configured to cut the pad, a roughness control part configured to support the cutting part and restrict an indentation depth of the cutting part, and a body part protruding from the substrate and configured to support the roughness control part and provided in plural on the substrate, wherein the cutting parts may have different protrusion heights, and a protruding member including a cutting part with a relatively larger protrusion height and a protruding member including a cutting part with a relatively smaller protrusion height may be disposed mixedly at a set ratio.

The protruding members arranged in a radial direction of the substrate may be configured to be disposed in a structure in which the roughness control part extends in the radial direction.

The protruding members arranged in a radial direction of the substrate may be configured to be disposed in a structure in which the roughness control part extends in a circumferential direction of the substrate.

When the protruding members are arranged in a radial direction of the substrate, the protruding members are configured so that a protruding member with the roughness control part extending in the radial direction of the substrate and a protruding member with the roughness control part extending in the circumferential direction of the substrate are disposed mixedly.

The protruding member may be provided in a plurality of divided areas along an edge perimeter of the substrate.

A width of the roughness control part may be the same as a width of the cutting part, and both side surfaces of the cutting part in a width direction may have a structure which is consecutively connected to both side surfaces of the roughness control part in the width direction, and a length of the roughness control part may be larger than a length of the cutting part, and both side surfaces of the cutting part in a longitudinal direction may have a structure which is disposed on an upper surface of the roughness control part and forms a step with both side surfaces of the roughness control part in the longitudinal direction.

A length of the roughness control part may be the same as a length of the body part, and both side surfaces of the roughness control part in a longitudinal direction may have a structure which is consecutively connected to both side surfaces of the body part in the longitudinal direction, and a width of the roughness control part may be smaller than a width of the body part, and both side surfaces of the roughness control part in a width direction may have a structure which is disposed on an upper surface of the body part and has a step with both side surfaces of the body part in the width direction.

The pad conditioner may further include a coating layer formed on a surface of the protruding member.

### BRIEF DESCRIPTION OF THE DRAWINGS

FIG. 1 is a plan view schematically illustrating a pad conditioner according to one embodiment of the present invention.

FIG. 2 is a perspective view schematically illustrating a protruding member in the pad conditioner of FIG. 1.

FIGS. 3A to 3C are respectively a plan view, side view, and front view schematically illustrating the protruding member of FIG. 2.

FIGS. 4A and 4B are respectively a side view and front view schematically illustrating a state in which a coating layer is formed on the protruding member of FIGS. 3B and 3C.

FIGS. 5A and 5B are views schematically illustrating portion “A” in FIG. 1.

FIGS. 6A and 6B are views schematically illustrating a modified example of portion “A” in FIG. 1.

FIG. 7 is a perspective view schematically illustrating an arrangement state of the protruding members in FIG. 1.

FIG. 8 is a plan view of FIG. 7.

FIG. 9 is a plan view schematically illustrating an arrangement state according to another embodiment of the protruding member.

FIG. 10 is a plan view schematically illustrating an arrangement state according to still another embodiment of the protruding member.

FIG. 11 is a plan view schematically illustrating an arrangement state of protruding members in each group when the protruding member is arranged in a plurality of groups.

FIG. 12 is a plan view schematically illustrating an arrangement state according to yet another embodiment of the protruding member.

FIGS. 13 and 14 are plan views schematically illustrating an arrangement state of protruding members with different sizes.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION OF THE INVENTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Advantages and features of the present disclosure and methods of achieving the advantages and features will be clear with reference to embodiments described in detail below together with the accompanying drawings. However, the present disclosure is not limited to the embodiments disclosed herein but will be implemented in various forms. The embodiments of the present disclosure are provided so that the present disclosure is completely disclosed, and a person with ordinary skill in the art can fully understand the scope of the present disclosure.

Meanwhile, the terms used in the present specification are for explaining the embodiments, not for limiting the present disclosure.

Terms, such as first, second, A, B, (a), (b) or the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

In a description of the embodiment, in a case in which any one element is described as being formed on or under another element, such a description includes both a case in which the two elements are formed in direct contact with each other and a case in which the two elements are in indirect contact with each other with one or more other elements interposed between the two elements. In addition, when one element is described as being formed on or under another element, such a description may include a case in which the one element is formed at an upper side or a lower side with respect to another element.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Hereinafter, embodiments of the present invention will be described in detail with reference to the accompanying drawings, and components which are the same or correspond to each other will be denoted by the same or corresponding reference numerals in all drawings, and redundant descriptions will be omitted.

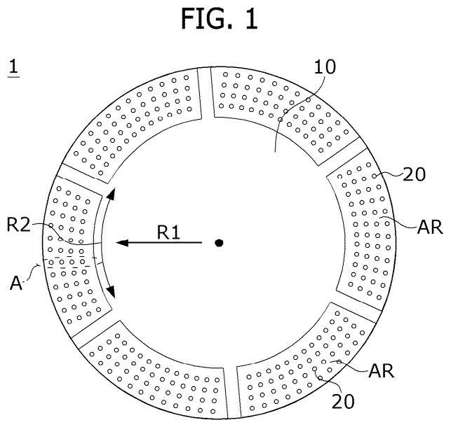

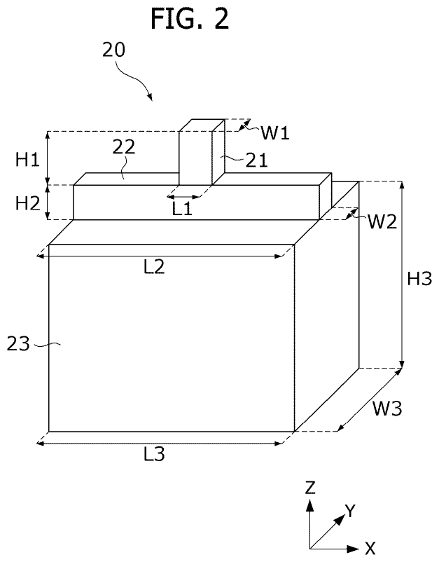

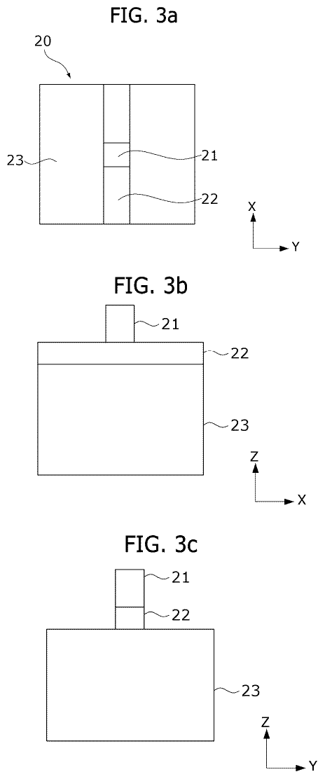

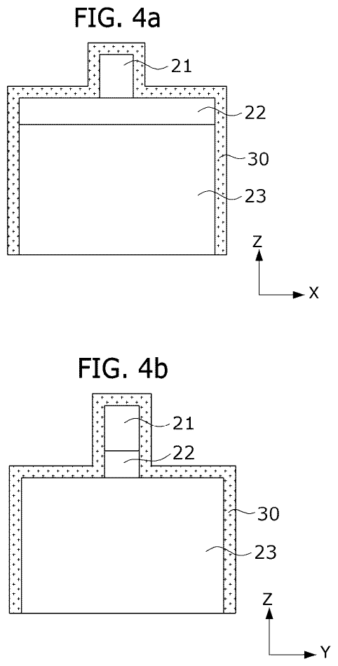

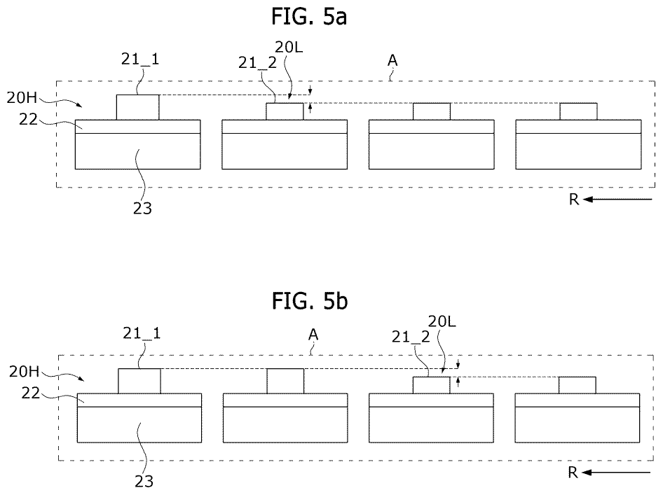

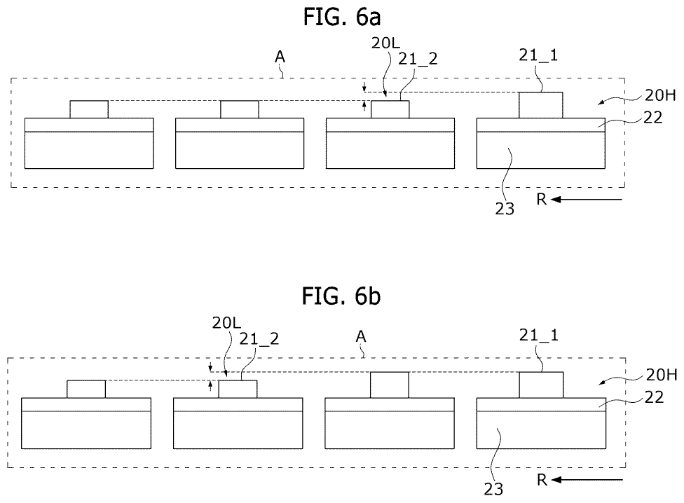

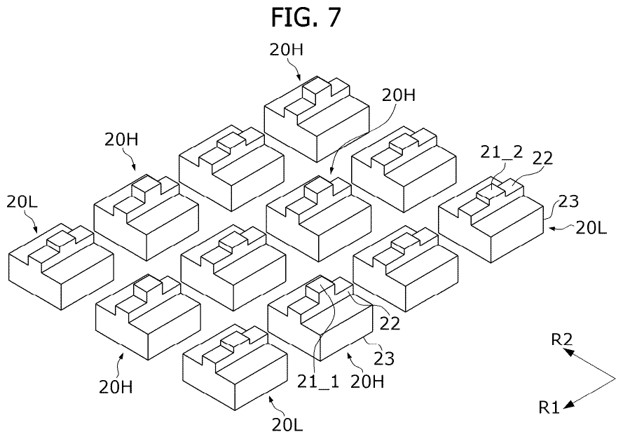

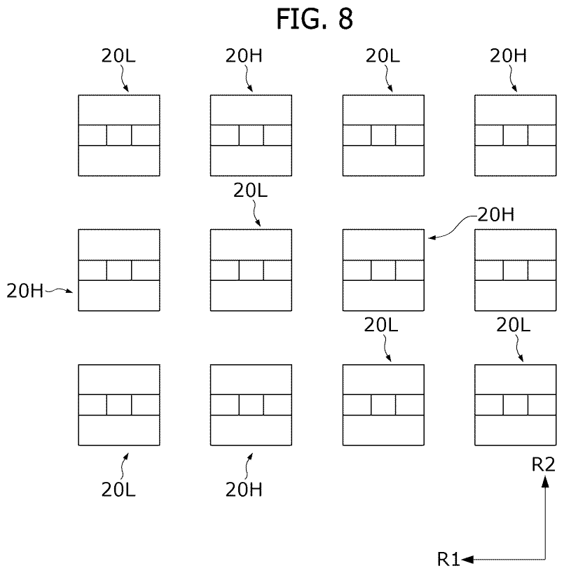

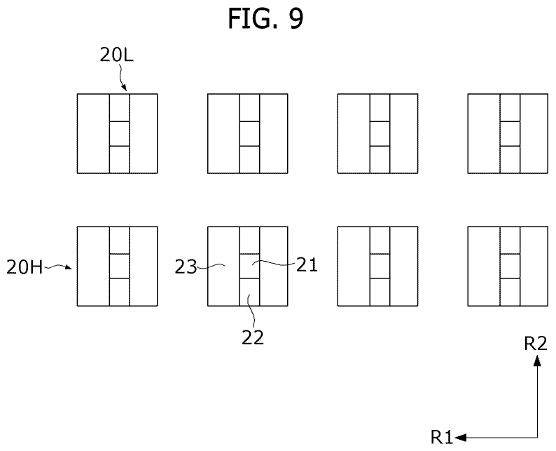

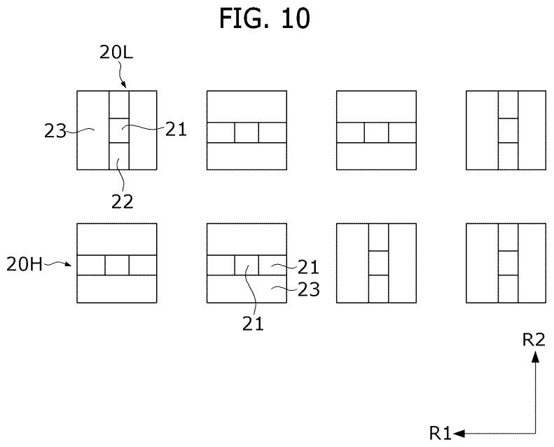

FIG. 1 is a plan view schematically illustrating a pad conditioner according to one embodiment of the present invention, FIG. 2 is a perspective view schematically illustrating a protruding member in the pad conditioner of FIG. 1, and FIGS. 3A to 3C are respectively a plan view, side view, and front view schematically illustrating the protruding member of FIG. 2. FIGS. 4A and 4B are respectively a side view and front view schematically illustrating a state in which a coating layer is formed on the protruding member of FIGS. 3B and 3C, FIGS. 5A and 5B are views schematically illustrating portion “A” in FIG. 1, and FIG. 6 is a view schematically illustrating a modified example of portion “A” in FIG. 1. FIG. 7 is a perspective view schematically illustrating an arrangement state of the protruding members in FIG. 1, and FIG. 8 is a plan view of FIG. 7. FIG. 9 is a plan view schematically illustrating an arrangement state according to another embodiment of the protruding member, and FIG. 10 is a plan view schematically illustrating an arrangement state according to still another embodiment of the protruding member.

Referring to the drawings, a pad conditioner 1 according to an embodiment of the present invention may be configured to dress a surface of a chemical mechanical (CMP) pad and may include a substrate 10 and a plurality of protruding members 20 arranged to protrude from the substrate 10. In addition, the pad conditioner 1 may further include a coating layer 30 formed on a surface of the protruding member 20.

The substrate 10 may be manufactured to have a disk shape using a material such as a metal, an alloy, or a ceramic with high strength and hardness. In one embodiment, the substrate 10 may be made of a tungsten carbide.

The protruding member 20 for cutting may be provided on one surface of the substrate 10, and a motor (not illustrated) for rotating the pad conditioner 1 may be connected to the other surface of the substrate 10.

The protruding member 20 may be formed to protrude upward from the planar substrate 10.

As illustrated in FIG. 4, the protruding member 20 may have a surface on which the coating layer 30 is formed, come into contact with the surface of the CMP pad by pressing in a state in which the coating layer 30 is formed, and cut the pad surface as the substrate 10 rotates.

The coating layer 30 may include polishing particles with high hardness, such as diamond and may be formed on the surface of the protruding member. The coating layer 30 is formed by coating the surface of the protruding member 20 with diamond particles with a diamond grain size of nano (nm) or micron (μm) by chemical vapor deposition (CVD). In an embodiment, the coating layer 30 may be formed in a thickness of about 10 μm

Since the coating layer 30 is the same as a diamond coating layer formed in a general CVD-type CMP pad conditioner, detailed description thereof will be omitted.

Hereinafter, the protruding member 20 will be described in more detail.

A plurality of protruding members 20 may be provided on the substrate 10 and disposed to be spaced apart from each other while maintaining a constant distance. In an embodiment, a distance between the protruding members 20 may range from about 300 to 1500 μm.

The protruding member 20 may be disposed along an edge perimeter of an edge area of the substrate 10. In this case, the protruding member 20 may be formed in a plurality of divided areas AR on the substrate 10. Of course, the protruding member 20 may be provided over the overall area of the substrate 10 or provided radially.

As illustrated in FIGS. 2 and 3, the protruding member 20 may be provided as a protruding structure with an overall rectangular shape.

The protruding member 20 may include a cutting part 21 for cutting the pad, a roughness control part 22 for supporting the cutting part 21 and restricting an indentation depth of the cutting part 21, and a body part 23 protruding from the substrate 10 and for supporting the roughness control unit 22.

In an embodiment, the cutting part 21, the roughness control part 22, and the body part 23 may be formed integrally. In addition, the protruding member 20 may be made of the same material as that of the substrate 10.

The body part 23 is formed to protrude upward from the surface of the substrate 10 at a predetermined height, the roughness control part 22 is formed to protrude upward from an upper surface of the body part 23, and the cutting part 21 is formed to protrude upward from an upper surface of the roughness control part 22.

Here, since an area of the upper surface of the body part 23 may be formed to be larger than an area of the upper surface of the roughness control part 22, and the area of the upper surface of the roughness control part 22 may be formed to be larger than an area of the upper surface of the cutting part 21, the protruding member 20 may be formed as a structure forming a three-stage stepped structure with respect to the substrate 10.

The body part 23 may have an overall quadrangular pillar shape.

The roughness control part 22 may extend horizontally from the upper surface of the body part 23 and may be formed so that the upper surface of the roughness control part 22 is parallel to the upper surface of the body part 23. In other words, the roughness control part 22 may be provided to protrude in a structure extending as much as a length L3 of the body part 23 from a center of the upper surface of the body part 23.

Referring to the drawings, a length L2 of the roughness control part 22 may be formed to be the same as the length L3 of the body part 23, and thus both side surfaces of the roughness control part 22 in a longitudinal direction may have a structure which is consecutively connected to both side surfaces of the body part 23 in the longitudinal direction.

In addition, a width W2 of the roughness control part 22 may be formed to be smaller than a width W3 of the body part 23, and thus both side surfaces of the roughness control part 22 in a width direction may form a step with both side surfaces of the body part 23 in the width direction without connection.

In addition, the roughness control part 22 may have a height H2 which is smaller than half a height H3 of the body part 23. When the height H2 of the roughness control part 22 is larger than or equal to half the height H3 of the body part 23, a problem that the cutting part 21 may not be sufficiently supported by a shear force applied to the cutting part 21 disposed above the roughness control part 22 may occur.

In the present embodiment, the longitudinal direction is defined as corresponding to an X-axis direction of the coordinate axis, the width direction is defined as corresponding to a Y-axis direction, and a vertical direction is defined as corresponding to a Z-axis direction.

Meanwhile, the cutting part 21 may extend in the vertical direction from the upper surface of the roughness control part 22 and may be formed so that an upper end surface of the cutting part 21 forms a step in parallel to the upper surface of the roughness control part 22.

Specifically, the width W1 of the cutting part 21 may be formed to be the same as the width W2 of the roughness control part 22, and thus both side surfaces of the cutting part 21 in the width direction may have a structure which is consecutively connected to the both side surfaces of the roughness control part 22 in the width direction.

In addition, the length L1 of the cutting part 21 may be formed to be smaller than the length L2 of the roughness control part 22, and thus the both side surfaces of the cutting part 21 may be disposed on the upper surface of the roughness control part 22 and may form a step with the both side surfaces of the roughness control part 22 in the longitudinal direction without connection.

In addition, a height H1 of the cutting part 21 may be formed to be at least the same as or larger than a height H2 of the roughness control part 22.

In order to secure high wafer polishing ability and the ability to maintain the same, it is necessary to increase the cutting amount of the pad. However, as the cutting amount of the pad increases, the roughness of the pad also tends to increase, and in this process, the pad is hardened due to inelastic deformation and fusion reaction with the slurry, resulting in the formation of protruded portions. The protruded portions increase the possibility of forming scratches on the wafer surface.

The protruding member 20 according to the embodiment of the present invention is provided with the roughness control part 22 between the cutting part 21 for cutting the pad and the body part 23 for supporting the cutting part 21 to control the roughness of the pad.

Specifically, the roughness control part 22 may restrict the indentation depth of the cutting part 21 to maintain a constant indentation depth. In addition, it is possible to cancel the height H1 deviation of the cutting part 21 which may be caused by processing errors. Therefore, it is possible to reduce performance deviation between products due to tip area errors and height deviation which occur during processing in conventional structures.

In addition, the roughness control part 22 may control the entirety of the roughness of the pad to be reduced by pushing and pressing protruded portions near the cutout portion of the pad with an effective pressure after cutting is performed, and thus it is possible to effectively reduce the frequency of the occurrence of the wafer scratches.

Meanwhile, the cutting part 21 provided on each protruding member 20 may have different protrusion heights. In addition, a protruding member 20H including a cutting part 21_1 with a relatively larger protrusion height and a protruding member 20 including a cutting part 21_2 with a relatively smaller protrusion height may be configured to be disposed mixedly at a set ratio.

In an embodiment, a ratio of the cutting part 21_1 with the relatively larger protrusion height may be configured to be smaller than a ratio of the cutting part 21_2 with the relatively smaller protrusion height. These ratios may be changed variously depending on the type of the pad.

FIG. 5 schematically illustrates portion “A” in FIG. 1.

In the present embodiment, although the four protruding members 20 are illustrated as being arranged in a row in a radial direction R1 with respect to the center of the substrate 10, the present invention is not limited thereto.

Referring to FIG. 5, when protruding members 20H and 20L provided with the cutting parts 21_1 and 21_2 with different protrusion heights are disposed, in each area AR, the protruding members 20H and 20L may be disposed in an edge area of the substrate 10 as the protrusion height of the cutting part 21_1 increases and disposed in a central area of the substrate 10 as the protrusion height of the cutting part 21_2 decreases.

In other words, the protruding member 20H provided in the edge area of the substrate 10 may include the cutting part 21_1 with the relatively highest protrusion height, and the protruding member 20L including the cutting part 21_2 with the relatively smaller protrusion height may be provided in the central area of the substrate 10. In addition, the protruding members 21H and 20L in each area may include the cutting parts 21_1 and 21_2 with the same protrusion height.

In an embodiment, as illustrated in FIG. 6, the protruding member 20L provided in the edge area of the substrate 10 may be provided with the cutting part 21_2 with the relatively smaller protrusion height, and the protruding member 20H including the cutting part 21_1 with the relatively larger protrusion height may be configured to be provided in the central area of the substrate 10.

In an embodiment, as illustrated in FIGS. 7 and 8, the protruding member 20H including the cutting part 21_1 with the relatively larger protrusion height and the protruding member 20L including the cutting part 21_2 with the relatively smaller protrusion height may be configured to be disposed mixedly.

In this case, the protruding member 20H including the cutting part 21_1 with the relatively larger protrusion height may be disposed not to overlap another adjacent protruding member 20H in a circumferential direction R2 (direction perpendicular to a radial direction) of the substrate 10, for example, in a zig-zag-shaped structure.

Meanwhile, as illustrated in FIGS. 5 to 8, when the protruding member 20 is disposed on the substrate 10, the roughness control part 22 is illustrated as being disposed in a structure extending in a radial direction R1, but the present invention is not limited thereto.

For example, as illustrated in FIG. 9, the protruding members 20 arranged side by side in the radial direction R1 of the substrate may be configured so that the roughness control part 22 is disposed in a structure extending in the circumferential direction R2.

In addition, as illustrated in FIG. 10, when the protruding members 20 are arranged in the radial direction R1 of the substrate, the protruding members 20 may be configured so that the protruding member 20 with the roughness control part 22 extending in the radial direction R1 of the substrate 10 and the protruding member 20 with the roughness control part 22 extending in the circumferential direction R2 of the substrate 10 are disposed mixedly.

Therefore, by constituting the extending direction of the roughness control part 22 so that the circumferential direction R2, and the circumferential direction R2 and the radial direction R1 are mixed, it is possible to reduce a magnitude of the shear force applied to the cutting part 21.

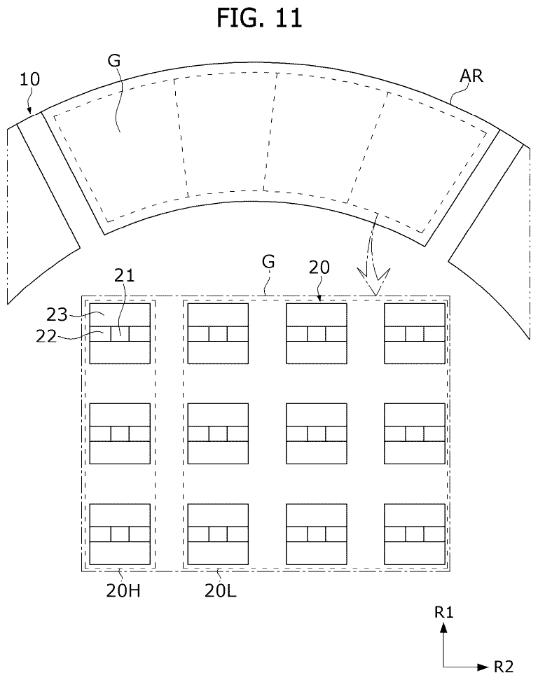

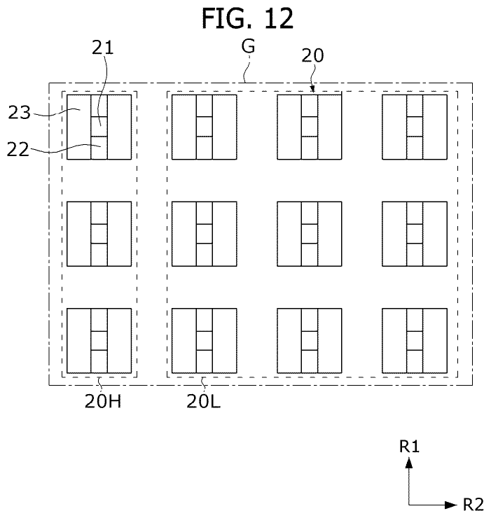

Meanwhile, FIG. 11 is a plan view schematically illustrating an arrangement state of protruding members in each group when the protruding member is arranged in a plurality of groups, and FIG. 12 is a plan view schematically illustrating an arrangement state according to yet another embodiment of the protruding member.

As illustrated in FIG. 11, the protruding members 20 may be arranged in a plurality of groups G in each area AR. In the present embodiment, although the plurality of protruding members 20 are illustrated as being partitioned into four groups G, the present invention is not limited thereto.

The protruding members 20 constituting each group G may be disposed in a structure in which the roughness control part 22 extends in the circumferential direction R2. In addition, the protruding member 20H including the cutting part 21_1 with the large protrusion height and the protruding member 20L including the cutting part 21_2 with the small protrusion height may be disposed mixedly.

In addition, as illustrated in FIG. 12, the protruding members of the adjacent group G may be disposed in a structure in which the roughness control part 22 extends in the radial direction R1.

Of course, when the protruding members 20 in the groups G constituting the same area AR are arranged, the extending directions of the roughness control parts 22 may be configured identically, and the protruding members 20 of the groups G constituting another area AR may be configured so that the extending directions of the roughness control parts 22 are different.

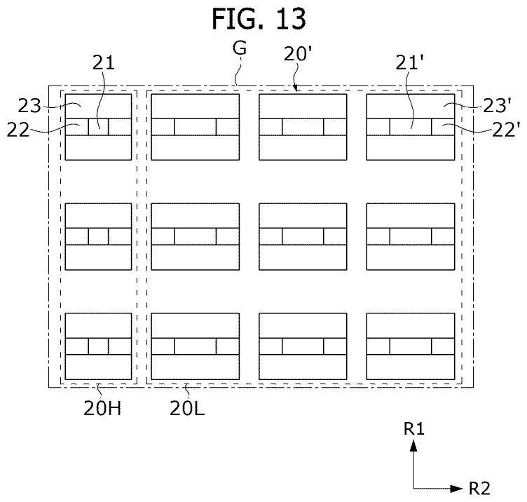

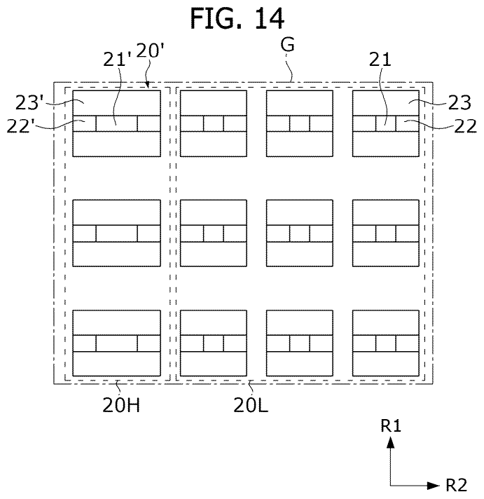

FIGS. 13 and 14 are plan views schematically illustrating an arrangement state of protruding members with different sizes.

As illustrated in FIGS. 13 and 14, each group G may be configured so that relatively smaller-sized protruding members 20 and relatively larger-sized protruding members 20′ are arranged mixedly.

In the present embodiment, although it is illustrated that the small-sized protruding member 20 has a substantially quadrangular structure and the large-sized protruding member 20′ has a substantially rectangular structure extending to one side, the present invention is not limited thereto. In an embodiment, the large-sized protruding member 20′ may be formed to have a structure which has larger lengths of a body part 23′, a roughness control part 22′, and a cutting part 21′ than the small-sized protruding member 20.

As illustrated in FIG. 13, when the small-sized protruding member 20 and the large-sized protruding member 20′ are arranged, the small-sized protruding member 20 may be composed of the protruding member 20H including the cutting part 21 with the large protrusion height, and the large-sized protruding member 20′ may be composed of the protruding member 20L including the cutting part 21′ with the small protrusion height.

In addition, as illustrated in FIG. 14, the large-sized protruding member 20′ may be composed of the protruding member 20H including the cutting part 21′ with the large protrusion height, and the small-sized protruding member 20 may be composed of the protruding member 20L including the cutting part 21 with the small protrusion height.

As described above, by mixedly arranging the protruding members 20H and 20L including the cutting parts 21_1 and 21_2 with different protrusion heights at the set ratio or mixedly arranging the large-sized protruding member 20′ and the small-sized protruding member 20, it is possible to obtain the entirely uniform operation effects without greatly affected by physical characteristics of the corresponding pads when the conditioning operation is performed on various types of pads.

In addition, by allowing new cutting to be performed through the protruding member 20L including the cutting part 21_2 with the relatively smaller height even when the protruding member 20H including the cutting part 21_1 with the relatively larger height is more worn at the beginning of conditioning, it is possible to prevent a degradation in conditioning efficiency, and by making the wearing of the cutting parts 21 of the protruding members 20 uniform, it is possible to expect the lifetime extension effect of the pad conditioner 1.

According to the embodiment of the present invention, it is possible to provide the pad conditioner capable of minimizing roughness generated during the conditioning operation and reducing performance deviation between products.

The effects of the present invention are not limited to the above-described effect, and other effects that are not mentioned will be able to be clearly understood by those skilled in the art from the following description.

Although the above description has been made with reference to the embodiments of the present invention, those skilled in the art will be able to understand that the present invention can be modified and changed variously without departing from the spirit and scope of the present invention described in the appended claims. In addition, differences related to these modifications and changes should be construed as being included in the scope of the present invention defined in the appended claims.

What is claimed is:

1. A pad conditioner configured to dress a surface of a chemical mechanical polishing (CMP) pad, comprising:
a substrate; and
a protruding member provided in plural on the substrate, the protruding member including a cutting part configured to cut the pad, a roughness control part configured to support the cutting part and restrict an indentation depth of the cutting part, and a body part protruding from the substrate and configured to support the roughness control part,
wherein the cutting parts have different protrusion heights, and a protruding member including a cutting part with a relatively larger protrusion height and a protruding member including a cutting part with a relatively smaller protrusion height are disposed mixedly at a set ratio.

2. The pad conditioner of claim 1, wherein the protruding members arranged in a radial direction of the substrate is configured to be disposed in a structure in which the roughness control part extends in the radial direction.

3. The pad conditioner of claim 1, wherein the protruding members arranged in a radial direction of the substrate is configured to be disposed in a structure in which the roughness control part extends in a circumferential direction of the substrate.

4. The pad conditioner of claim 1, wherein, when the protruding members are arranged in a radial direction of the substrate, the protruding members are configured so that a protruding member with the roughness control part extending in the radial direction of the substrate and a protruding member with the roughness control part extending in the circumferential direction of the substrate are disposed mixedly.

5. The pad conditioner of claim 1, wherein the protruding member is provided in a plurality of divided areas along an edge perimeter of the substrate.

6. The pad conditioner of claim 1, wherein a width of the roughness control part is the same as a width of the cutting part, and both side surfaces of the cutting part in a width direction have a structure which is consecutively connected to both side surfaces of the roughness control part in the width direction, and
a length of the roughness control part is larger than a length of the cutting part, and both side surfaces of the cutting part in a longitudinal direction have a structure which is disposed on an upper surface of the roughness control part and forms a step with both side surfaces of the roughness control part in the longitudinal direction.

7. The pad conditioner of claim 1, wherein a length of the roughness control part is the same as a length of the body part, and both side surfaces of the roughness control part in a longitudinal direction have a structure which is consecutively connected to both side surfaces of the body part in the longitudinal direction, and
a width of the roughness control part is smaller than a width of the body part, and both side surfaces of the roughness control part in a width direction have a structure which is disposed on an upper surface of the body part and has a step with both side surfaces of the body part in the width direction.

8. The pad conditioner of claim 1, further comprising a coating layer formed on a surface of the protruding member.
